(19) United States
(12) Patent Application Publication
(10) Pub. No.: US 2026/0297744 A1
(43) Pub. Date: Oct. 1, 2026

(54) METHOD OF FORMING GALLIUM OXYNITRIDE LAYER

(71) Applicant: JUSUNG ENGINEERING CO., LTD., Gwangju-si, Gyeonggi-do (KR)

(72) Inventors: Gyeong Hun WON, Yongin-si, Gyeonggi-do (KR); Seo Jun YOON, Yongin-si, Gyeonggi-do (KR); Min Woo AHN, Yongin-si, Gyeonggi-do (KR); Chul Joo HWANG, Yongin-si, Gyeonggi-do (KR)

(21) Appl. No.: 19/480,312

(22) PCT Filed: May 13, 2024
(86) PCT No.: PCT/KR2024/006469

§ 371 Date: Oct. 30, 2025

(30) Foreign Application Priority Data
May 26, 2023 (KR) 10-2023-0068665

(51) Int. Cl. C23C 16/455; C23C 16/30

(52) U.S. Cl. CPC C23C 16/45531; C23C 16/308; C23C 16/45536; C23C 16/45553

(57) ABSTRACT

Disclosed is a method of forming the gallium oxynitride layer comprising a process of injecting a source material containing gallium; a process of forming a gallium nitride layer by injecting a first reactant material containing nitrogen; and a process of forming a gallium oxynitride layer by injecting a second reactant material containing oxygen onto the gallium nitride layer.

### CROSS-REFERENCE TO RELATED APPLICATIONS

This application claims the benefit of the Korean Patent Application No. 10-2023-0068665 filed on May 26, 2023, which is hereby incorporated by reference as if fully set forth herein.

### BACKGROUND

### Technical Field

The present disclosure relates to a method of forming a gallium oxynitride layer.

### Description of the Related Art

Oxide semiconductors have the advantage of being able to easily obtain desired physical properties because they have high mobility and can have a large resistance change depending on the oxygen content. In addition, the manufacturing cost is low because the oxide constituting the oxide semiconductor layer may be formed at a relatively low temperature in the manufacturing process of the oxide semiconductor.

There may be various methods of depositing the oxide semiconductor. For example, the oxide semiconductor may be deposited using atomic layer deposition (ALD) or chemical vaporization deposition (CVD). However, when depositing the oxide semiconductor by using one method of ALD and CVD, there is a problem in that the film quality of the oxide semiconductor is uneven or it takes a long time to form the oxide semiconductor.

Furthermore, when the atomic layer deposition method (ALD) is used as a method of depositing an oxide semiconductor, for example, the oxide semiconductor layer may be formed by depositing a source material and a reactant material. In this case, after the process of injecting the source material and the process of injecting the reactant material, an unnecessary source material or reactant material may remain in the chamber, which may be a factor that inhibits the film quality of the oxide semiconductor.

### SUMMARY

the present disclosure is designed to overcome the disadvantages of the above-described gallium oxide layer manufacturing method, and it is intended to provide a method of forming a gallium oxide layer capable of reducing the time it takes to deposit the gallium oxide layer while forming an excellent film quality of the gallium oxide layer.

In accordance with an aspect of the present disclosure, the above and other objects can be accomplished by the provision of A method of forming the gallium oxynitride layer comprising a process of injecting a source material containing gallium; a process of forming a gallium nitride layer by injecting a first reactant material containing nitrogen; and a process of forming a gallium oxynitride layer by injecting a second reactant material containing oxygen onto the gallium nitride layer.

And the above and other objects can be accomplished by the provision of the method of forming the gallium oxynitride layer wherein the source material includes trimethyl gallium (TMGa).

And the above and other objects can be accomplished by the provision of the method of forming the gallium oxynitride layer wherein the first reactant material includes any one of nitrogen (N2) and ammonia (NH3).

And the above and other objects can be accomplished by the provision of the method of forming the gallium oxynitride layer wherein the second reactant material includes any one of oxygen (O2) and nitrous oxide (N2O).

And the above and other objects can be accomplished by the provision of the method of forming the gallium oxynitride layer further comprising a process of forming a plasma containing hydrogen (H2) gas or argon (Ar) gas between the process of injecting the source material and the process of injecting the first reactant material.

And the above and other objects can be accomplished by the provision of the method of forming the gallium oxynitride layer wherein the process of injecting the first reactant material includes a process of forming plasma containing oxygen.

And the above and other objects can be accomplished by the provision of the method of forming the gallium oxynitride layer further comprising a process of forming a plasma containing hydrogen (H2) gas or argon (Ar) gas after the process of injecting the second reactant material.

And the above and other objects can be accomplished by the provision of a method of forming a gallium oxynitride layer comprising a process of forming a first gallium oxynitride layer on the substrate; and a process of forming a second gallium oxynitride layer on the first gallium oxynitride layer, wherein any one of the process of forming the first gallium oxynitride layer and the process of forming the second gallium oxynitride layer uses an atomic layer deposition method (ALD), and another one of the process of forming the first gallium oxynitride layer and the process of forming the second gallium oxynitride layer uses a chemical vaporization deposition method (CVD).

And the above and other objects can be accomplished by the provision of the method of forming the gallium oxynitride layer wherein the process of forming the first gallium oxynitride layer uses an atomic layer deposition method (ALD), and the process of forming the second gallium oxynitride layer uses a chemical vaporization deposition method (CVD).

And the above and other objects can be accomplished by the provision of the method of forming the gallium oxynitride layer further comprising a process of forming a third gallium oxynitride layer on the second gallium oxynitride layer, wherein the process of forming the third gallium oxynitride layer uses an atomic layer deposition method (ALD).

And the above and other objects can be accomplished by the provision of the method of forming the gallium oxynitride layer wherein the process of forming the first gallium oxynitride layer uses a chemical vaporization deposition method (CVD), and the process of forming the second gallium oxynitride layer uses an atomic layer deposition method (ALD).

And the above and other objects can be accomplished by the provision of the method of forming the gallium oxynitride layer further comprising a process of forming a third gallium oxynitride layer on the second gallium oxynitride layer, wherein the process of forming the third gallium oxynitride layer uses a chemical vaporization deposition (CVD).

And the above and other objects can be accomplished by the provision of the method of forming the gallium oxynitride layer wherein a process of forming any one of the first gallium oxynitride layer and the second gallium oxynitride layer using the atomic layer deposition method (ALD) uses the method of forming the gallium oxynitride layer.

And the above and other objects can be accomplished by the provision of the method of forming the gallium oxynitride layer wherein a process of forming any one of the first gallium oxynitride layer and the second gallium oxynitride layer using the chemical vaporization deposition method (CVD) includes a process of injecting a source material including gallium (Ga), a first reactant material including nitrogen, and a second reactant material including oxygen.

And the above and other objects can be accomplished by the provision of the method of forming the gallium oxynitride layer wherein the source material includes trimethyl gallium (TMGa), the first reactant material includes any one of nitrogen (N2) and ammonia (NH3), and the second reactant material includes any one of oxygen (O2) and nitrous oxide (N2O).

And the above and other objects can be accomplished by the provision of the method of forming the gallium oxynitride layer, further comprising a process of forming plasma containing hydrogen (H2) gas or argon (Ar) gas after the process of injecting the source material, the first reactant material and the second reactant material.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic cross-sectional view of a gallium oxynitride layer according to an embodiment of the present disclosure.

FIG. 2 is a schematic cross-sectional view of a gallium oxynitride layer according to another embodiment of the present disclosure.

FIG. 3 is a schematic flowchart of a method of forming a gallium oxynitride layer according to an embodiment of the present disclosure.

FIG. 4 is a schematic flowchart of a method of forming a gallium oxynitride layer according to another embodiment of the present disclosure.

FIG. 5 is a schematic flowchart of a method of forming a gallium oxynitride layer according to another embodiment of the present disclosure.

FIG. 6 is a schematic flowchart of a method of forming a gallium oxynitride layer according to another embodiment of the present disclosure.

FIG. 7 is a schematic cross-sectional view of a gallium oxynitride layer according to another embodiment of the present disclosure.

FIG. 8 is a schematic cross-sectional view of a gallium oxynitride layer according to another embodiment of the present disclosure.

FIG. 9 is a schematic flowchart of a method of forming a gallium oxynitride layer according to another embodiment of the present disclosure.

FIG. 10 is a schematic flowchart of a method of forming a gallium oxynitride layer according to another embodiment of the present disclosure.

FIG. 11 is a schematic flowchart of a method of forming a gallium oxynitride layer according to another embodiment of the present disclosure.

FIG. 12 is a schematic flowchart of a method of forming a gallium oxynitride layer according to another embodiment of the present disclosure.

FIG. 13 is a view illustrating a gallium oxynitride layer manufacturing apparatus according to another embodiment of the present disclosure.

### DETAILED DESCRIPTION DISCLOSURE

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

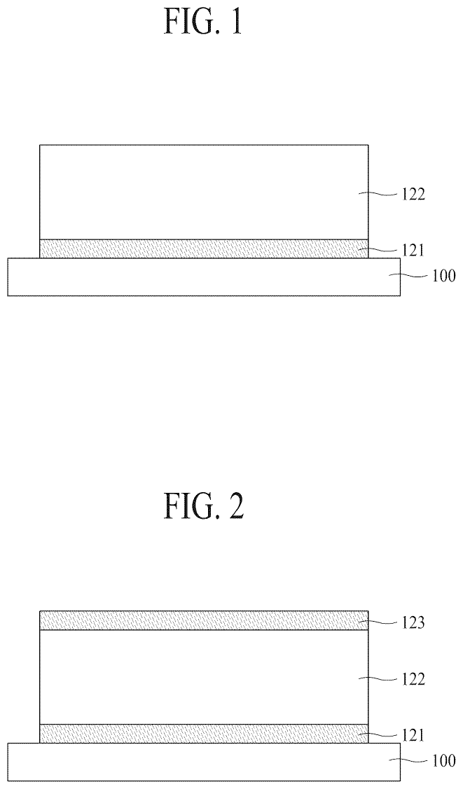

FIG. 1 is a schematic cross-sectional view of a gallium oxynitride layer according to an embodiment of the present disclosure.

As shown in FIG. 1, the gallium oxynitride layer according to an embodiment of the present disclosure includes a first gallium oxynitride layer 121 and a second gallium oxynitride layer 122. In this case, the first gallium oxynitride layer may be formed through atomic layer deposition (ALD), and the second gallium oxynitride layer may be formed through chemical vaporization deposition (CVD).

The first gallium oxynitride layer 121 is formed on the substrate 100. In this case, the substrate 100 may be a glass or silicon (Si) wafer, but is not limited thereto.

The first gallium oxynitride layer 121 may include an oxide semiconductor, for example, the first gallium oxynitride layer 121 may include a gallium oxynitride (GaON)-based oxide semiconductor containing gallium.

The first gallium oxynitride layer 121 may be formed using atomic layer deposition (ALD). Since the first gallium oxynitride layer 121 is formed using the atomic layer deposition method, the film quality of the first gallium oxynitride layer 121 is excellent.

Meanwhile, the first gallium oxynitride layer 121 may be formed using plasma enhanced atomic layer deposition (PEALD).

The second gallium oxynitride layer 122 is formed on the first gallium oxynitride layer 121.

The second gallium oxynitride layer 122 may include an oxide semiconductor, for example, the second gallium oxynitride layer 122 may include a gallium oxynitride (GaON)-based oxide semiconductor containing gallium.

The second gallium oxynitride layer 122 may be formed using a chemical vaporization deposition (CVD). When the second gallium oxynitride layer 122 is formed using the chemical vaporization deposition method, the second gallium oxynitride layer 122 may be formed faster than a case using an atomic layer deposition method.

Meanwhile, the second gallium oxynitride layer 122 may be formed using plasma enhanced chemical vaporization deposition (PECVD).

FIG. 2 is a schematic cross-sectional view of a gallium oxynitride layer according to another embodiment of the present disclosure.

As shown in FIG. 2, the gallium oxynitride layer according to another embodiment of the present disclosure includes a first gallium oxynitride layer 121, a second gallium oxynitride layer 122, and a third gallium oxynitride layer 123. Meanwhile, the gallium oxynitride layer according to an embodiment of FIG. 2 is the same as the gallium oxynitride layer according to an embodiment of FIG. 1, except for the third gallium oxynitride layer 123, and thus different configurations will be mainly described below.

The first gallium oxynitride layer 121 is formed using an atomic layer deposition method, and the second gallium oxynitride layer 122 is formed using a chemical vaporization deposition method.

The third gallium oxynitride layer 123 is formed on the second gallium oxynitride layer 122.

The third gallium oxynitride layer 123 may include an oxide semiconductor, for example, the third gallium oxynitride layer 123 may include a gallium oxynitride (GaON)-based oxide semiconductor containing gallium.

The third gallium oxynitride layer 123 may be formed using atomic layer deposition (ALD). Since the third gallium oxynitride layer 123 is formed using the atomic layer deposition method, the film quality of the third gallium oxynitride layer 123 is excellent.

Meanwhile, the third gallium oxynitride layer 123 may be formed using plasma enhanced atomic layer deposition (PEALD).

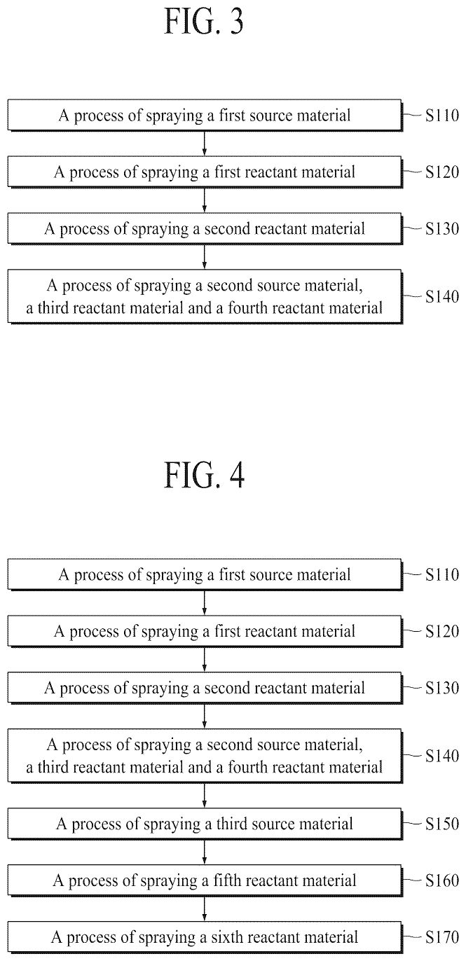

FIG. 3 is a schematic flowchart of a method of forming a gallium oxynitride layer according to an embodiment of the present disclosure.

As shown in FIG. 3, the method of forming a gallium oxynitride layer according to an embodiment of present disclosure includes a process S110 of injecting a first source material, a process S120 of injecting a first reactant material, a process S130 of injecting a second reactant material, and a process S140 of injecting a second source material, a third reactant material and a fourth reactant material.

In this case, atomic layer deposition (ALD) may be used for the process S110 of injecting the first source material, the process S120 of injecting the first reactant material, and the process S130 of injecting the second reactant material.

Therefore, the process S110 of injecting the first source material, the process S120 of injecting the first reactant material, and the process S130 of injecting the second reactant material may be performed in a vacuum chamber. Specifically, the substrate 100 may be placed on a susceptor provided below the vacuum chamber, and the first source material, the first reactant material, and the second reactant material may be injected through a gas injection hole provided above the vacuum chamber to form the first gallium oxynitride layer (see FIGS. 1 and 2) on the substrate 100.

When using the atomic layer deposition method, the process of injecting the first source material onto the substrate 100, then injecting the first reactant material, and then injecting the second reactant material may be repeated in one cycle.

In the process S110 of injecting the first source material, the first source material may include a material containing gallium (Ga). In this case, the material may be a precursor material or a gas material.

The material containing gallium (Ga) may be, for example, trimethyl gallium (TMGa). Meanwhile, the material containing gallium (Ga) is not limited thereto, and may be variously changed according to knowledge in the art.

After the process S110 of injecting the first source material, the process S120 of injecting the first reactant material may be performed.

When the first source material includes a material containing gallium (Ga), the first reactant material may include any one of ammonia (NH3) and nitrogen (N2).

When the process S120 of injecting the first reactant material is performed, the first reactant material may be injected without forming or forming plasma.

In this case, when plasma is not formed in the process S120 of injecting the first reactant material, the first gallium oxynitride layer is formed using atomic layer deposition (ALD), and when plasma is formed in the process S120 of injecting the first reactant material, the first gallium oxynitride layer may be formed using plasma-enhanced atomic layer deposition (PEALD).

When the process S120 of injecting the first reactant material is performed using the plasma-enhanced atomic layer deposition method, the plasma may include oxygen (O2).

After the process S120 of injecting the first reactant material, the process S130 of injecting the second reactant material may be performed.

When the first source material includes gallium (Ga), the second reactant material may include any one of oxygen (O2) and nitrous oxide (N2O), and in this case, gallium oxynitride (GaON) may be obtained as the first gallium oxynitride layer (see 121 of FIGS. 1 and 2).

When the process S130 of injecting the second reactant material is performed, the second reactant material may be injected without forming or forming plasma.

In this case, when plasma is not formed in the process S130 of injecting the second reactant material, the first gallium oxynitride layer is formed using atomic layer deposition (ALD), and when plasma is formed in the process S130 of injecting the second reactant material, the first gallium oxynitride layer may be formed using plasma-enhanced atomic layer deposition (PEALD).

When the process S130 of injecting the second reactant material is performed using the plasma-enhanced atomic layer deposition, the plasma may include oxygen (O2).

The first gallium oxynitride layer may be formed by an atomic layer deposition method (ALD or PEALD), so that the film quality may be excellent.

After the process S130 of injecting the second reactant material, the process S140 of injecting the second source material, the third reactant material, and the fourth reactant material may be performed.

The process S140 of injecting the second source material, the third reactant material, and the fourth reactant material may use a chemical vaporization deposition (CVD). In this case, the second gallium oxynitride layer may be formed through the gas injection hole in the chamber in which the process S110 of injecting the first source material, the process S120 of injecting the first reactant material, and the process S130 of injecting the second reactant material are performed. The second source material, the third reactant material, and the fourth reactant material are simultaneously injected onto the first gallium oxynitride layer (see 121 of FIGS. 1 and 2) through the gas injection hole, thereby forming the second gallium oxynitride layer (see 122 of FIGS. 1 and 2) on the first gallium oxynitride layer (see 121 of FIGS. 1 and 2) by a chemical vaporization deposition method.

The second source material may be a material containing gallium (Ga). In this case, the second source material may include, for example, trimethyl gallium (TMGa).

The third reactant material may include any one of ammonia (NH3) and nitrogen (N2), and the fourth reactant material may include any one of oxygen (O2) and nitrous oxide (N2O).

When the second source material includes a material containing gallium (Ga), the third reactant material includes either ammonia (NH3) or nitrogen (N2), and the fourth reactant material includes either oxygen (O2) or nitrous oxide (N2O), gallium oxynitride (GaON) may be obtained as the second gallium oxynitride layer (see 122 in FIGS. 1 and 2).

When the process S140 of injecting the second source material, the third reactant material, and the fourth reactant material is performed, the second source material, the third reactant material and the fourth reactant material may be injected without forming or forming plasma.

In this case, when plasma is not formed in the process S140 of injecting the second source material, the third reactant material, and the fourth reactant material, the second gallium oxynitride layer (see 122 of FIGS. 1 and 2) is formed using a chemical vaporization deposition method (CVD), and when plasma is formed in the process S140 of injecting the second source material, the third reactant material, and the fourth reactant material, the second gallium oxynitride layer (see 122 of FIGS. 1 and 2) may be formed using a plasma enhancement chemical vaporization deposition method (PECVD). In this case, the plasma may include oxygen (O2).

The second gallium oxynitride layer (see 122 of FIGS. 1 and 2) may be formed by chemical vaporization deposition (CVD or PECVD), and thus a deposition time may be shortened.

Although not shown, a process of injecting a purge gas may be added between each of the processes S110, S120, S130, and S140. For example, a process of injecting a purge gas may be added between the process S110 of injecting the first source material and the process S120 of injecting the first reactant material, and a process of injecting a purge gas may be added between the process S120 of injecting the first reactant material and the process S130 of injecting the second reactant material, and a process of injecting a purge gas may be added between the process S130 of injecting the second reactant material and the process S140 of injecting the second source material, the third reactant material, and the fourth reactant material.

FIG. 4 is a schematic flowchart of a method of forming a gallium oxynitride layer according to another embodiment of the present disclosure.

As shown in FIG. 4, the method of forming a gallium oxynitride layer according to another embodiment of the present disclosure includes the method of forming a gallium oxynitride layer according to the present disclosure, except for the process S110 of injecting a first source material, the process S120 of injecting a first reactant material, the process S130 of injecting a second reactant material, the process S140 of injecting a second source material, the third reactant material, and the fourth reactant material, the process S150 of injecting a third source material, the process S160 of injecting a fifth reactant material, and the process S170 of injecting a sixth reactant material. In this case, the method of forming a gallium oxynitride layer according to FIG. 4 is the same as the method of forming a gallium oxynitride layer according to FIG. 3, except for the process S150 of injecting the third source material, the process S160 of injecting a fifth reactant material, and the process S170 of injecting a sixth reactant material, and thus different configurations will be mainly described below.

Atomic layer deposition (ALD) may be used in the process S150 of injecting the third source material, the process S160 of injecting the fifth reactant material, and the process S170 of injecting the sixth reactant material.

Therefore, the process S150 of injecting the third source material, the process S160 of injecting the fifth reactant material, and the process S170 of injecting the sixth reactant material may be performed in a vacuum chamber. Specifically, the substrate 100 on which the first gallium oxynitride layer and the second gallium oxynitride layer are formed is placed on a susceptor provided below the vacuum chamber, and the third source material, the fifth reactant material, and the sixth reactant material may be injected through a gas injection hole provided above the vacuum chamber to form the third gallium oxynitride layer (see 123 of FIG. 2) on the second gallium oxynitride layer.

When using the atomic layer deposition method, the process of injecting the third source material onto the substrate 100, then injecting the fifth reactant material, and then injecting the sixth reactant material may be repeated in one cycle.

The process S150 of injecting the third source material may be performed after the process S140 of injecting the second source material, the third reactant material and the fourth reactant material.

In the process S150 of injecting the third source material, the third source material may include a material containing gallium (Ga). In this case, the material may be a precursor material or a gas material.

The material containing gallium (Ga) may be, for example, trimenthyl gallium (TMGa). Meanwhile, the material containing gallium (Ga) is not limited thereto, and may be variously changed according to knowledge in the art.

After the process S150 of injecting the third source material, the process S160 of injecting the fifth reactant material may be performed.

When the third source material includes a material containing gallium (Ga), the fifth reactant material may include any one of ammonia (NH3) and nitrogen (N2).

When the process S160 of injecting the fifth reactant material is performed, the fifth reactant material may be injected without forming or forming plasma.

In this case, when plasma is not formed in the process S160 of injecting the fifth reactant material, the third gallium oxynitride layer is formed using atomic layer deposition (ALD), and when plasma is formed in the process S160 of injecting the fifth reactant material, the third gallium oxynitride layer may be formed using plasma reinforced atomic layer deposition (PEALD).

When the process S160 of injecting the fifth reactant material is performed using the plasma-enhanced atomic layer deposition method, the plasma may include oxygen (O2).

After performing the process S160 of injecting the fifth reactant material, the process S170 of injecting the sixth reactant material may be performed.

When the third source material includes gallium (Ga), the sixth reactant material may include any one of oxygen (O2) and nitrous oxide (N2O), and in this case, gallium oxynitride (GaON) may be obtained as the third gallium oxynitride layer (see 123 of FIG. 2).

When the process S170 of injecting the sixth reactant material is performed, the sixth reactant material may be injected without forming or forming plasma.

In this case, when plasma is not formed in the process S170 of injecting the sixth reactant material, the third gallium oxynitride layer (see 123 of FIG. 2) is formed using atomic layer deposition (ALD), and when plasma is formed in the process S170 of injecting the sixth reactant material, the third gallium oxynitride layer (see 123 of FIG. 2) may be formed using plasma enhancement atomic layer deposition (PEALD).

When the process S170 of injecting the sixth reactant material is performed using the plasma-enhanced atomic layer deposition, the plasma may include oxygen (O2).

The third gallium oxynitride layer (see 123 of FIG. 2) may be formed by atomic layer deposition (ALD or PEALD), and thus may have excellent film quality.

Although not illustrated, a process of injecting a purge gas may be added between each of the processes S110, S120, S130, S140, S150, S160, and S170. For example, a process of injecting a purge gas may be added between the process S110 of injecting the first source material and the process S120 of injecting the first reactant material, a process of injecting a purge gas may be added between the process S120 of injecting the first reactant material and the process S130 of injecting the second reactant material and the process S140 of injecting the second source material, the third reactant material and the fourth reactant material. A process of injecting a purge gas may be added between the process S140 of injecting the second source material, the third reactant material, and the fourth reactant material and the process S150 of injecting the third source material. A process of injecting a purge gas may be added between the process S150 of injecting the third source material and the process S160 of injecting the fifth reactant material. A process of injecting a purge gas may be added between the process S160 of injecting the fifth reactant material and the process S170 of injecting the sixth reactant material.

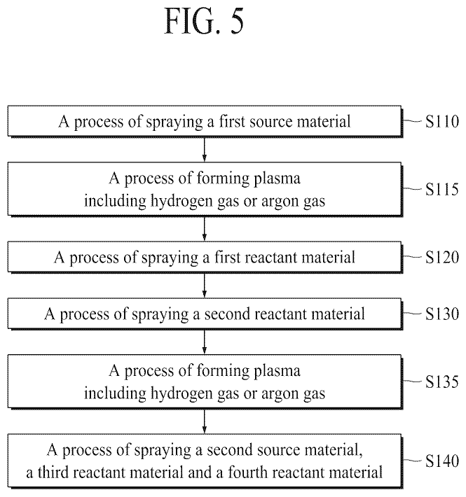

FIG. 5 is a schematic flowchart of a method of forming a gallium oxynitride layer according to another embodiment of the present disclosure.

As shown in FIG. 5, the method of forming a gallium oxynitride layer according to another embodiment of the present disclosure includes the process S110 of injecting a first source material, the process S115 of forming plasma including hydrogen gas or argon gas, the process S120 of injecting a first reactant material, the process S130 of injecting a second reactant material, the process S135 of forming plasma including hydrogen gas or argon gas, and the process S140 of injecting a second source material, a third reactant material, and a fourth reactant material. In this case, the method of forming the gallium oxynitride layer according to FIG. 5 is the same as the method of forming the gallium oxynitride layer according to FIG. 3 except for the processes S115 and S135 of forming the plasma including the hydrogen gas or argon gas, and thus different configurations will be mainly described below.

The processes S115 and S135 of forming the plasma including hydrogen or argon gas may be performed after the process S110 of injecting the first source material or the process S130 of injecting the second reactant material.

In the processes S115 and S135 of forming the plasma including the hydrogen or argon gas, the plasma including the hydrogen gas (H2) or the argon (Ar) gas may be formed in the chamber. Specifically, by performing the process S110 of injecting the first source material, the plasma including the hydrogen or argon gas may be applied on the substrate 100 to which the first source material is adsorbed, and in this case, impurities remaining on the substrate 100 may be removed without being adsorbed.

Alternatively, plasma containing the hydrogen or argon gas may be applied to the substrate 100 on which the first gallium oxynitride layer is formed by reacting the first source material, the first reactant material, and the second reactant material after the process S130 of injecting the second reactant material, and in this case, impurities remaining without reacting on the substrate 100 may be removed.

Therefore, the content of impurities on the surface or inside of the first gallium oxynitride layer formed when the process S110 of injecting the first source material, the process S120 of injecting the first reactant material, and the process S130 of injecting the second reactant material is performed using atomic layer deposition may be minimized.

Although not shown, after the process S140 of injecting the second source material, the third reactant material, and the fourth reactant material, a process of forming plasma including hydrogen gas or argon gas may be additionally included.

Although not shown, a process of injecting a purge gas may be added between each of the processes S110, S115, S120, S130, S135, and S140.

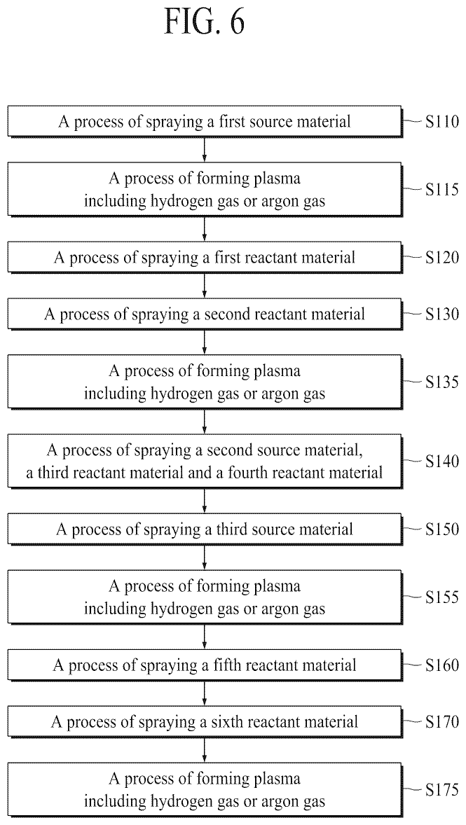

FIG. 6 is a schematic flowchart of a method of forming a gallium oxynitride layer according to another embodiment of the present disclosure.

As can be seen from FIG. 6, the method of forming a gallium oxynitride layer according to another embodiment of the present disclosure includes the process S110 of injecting a first source material, the process S115 of forming plasma containing hydrogen gas or argon gas, the process S120 of injecting a first reactant material, the process S130 of injecting a second reactant material, the process S135 of forming a plasma containing hydrogen gas or argon gas, the process S140 of injecting the second source material, the third reactant material, and the fourth reactant material, the process S150 of injecting a third source material, the process S155 of forming a plasma containing hydrogen gas or argon gas, the process S160 of injecting a fifth reactant material, the process S170 of injecting a sixth reactant material, and the process S175 of forming a plasma containing hydrogen gas or argon gas.

In this case, the method of forming the gallium oxynitride layer according to FIG. 6 is the same as the method of forming the gallium oxynitride layer according to FIG. 5 except for the process S150 of injecting the third source material to the process S175 of forming the plasma including the hydrogen gas or argon gas.

The process S150 of injecting the third source material, the process S160 of injecting the fifth reactant material, and the process S170 of injecting the sixth reactant material are the same as the process of injecting the third source material, the process of injecting the fifth reactant material, and the process of injecting the sixth reactant material according to FIG. 4. Therefore, the process S150 of injecting the third source material, the process S160 of injecting the fifth reactant material, and the process S170 of injecting the sixth reactant material may use atomic layer deposition, and in this case, the third gallium oxynitride layer may be formed.

The processes S155 and S175 of forming the plasma including hydrogen or argon gas may be performed after the process S150 of injecting the third source material or the process S170 of injecting the sixth reactant material.

In the processes S155 and S175 of forming the plasma including the hydrogen or argon gas, the plasma including the hydrogen gas (H2) or the argon (Ar) gas may be applied into the chamber. Specifically, by performing the process S150 of injecting the third source material, the plasma including the hydrogen or argon gas may be applied on the second gallium oxynitride layer to which the third source material is adsorbed, and in this case, impurities remaining on the substrate 100 without being adsorbed may be removed.

Alternatively, plasma containing the hydrogen or argon gas may be applied to the substrate 100 on which the third gallium oxynitride layer is formed by reacting the third source material, the fifth reactant material, and the sixth reactant material after the process S170 of injecting the sixth reactant material, and impurities remaining without reacting on the substrate 100 may be removed.

Therefore, the content of impurities on the surface or inside of the third gallium oxynitride layer formed when the process S150 of injecting the third source material, the process S160 of the injecting the fifth reactant material, and the process S170 of injecting the sixth reactant material are performed using atomic layer deposition may be minimized.

Although not shown, a process of forming a plasma including hydrogen gas or argon gas between the process S140 of injecting the second source material, the third reactant material, and the fourth reactant material and the process S150 of injecting the third source material may be additionally included.

Although not shown, a process of injecting a purge gas may be added between each of the processes S110, S115, S120, S130, S135, S140, S150, S155, S160, S170, and S175.

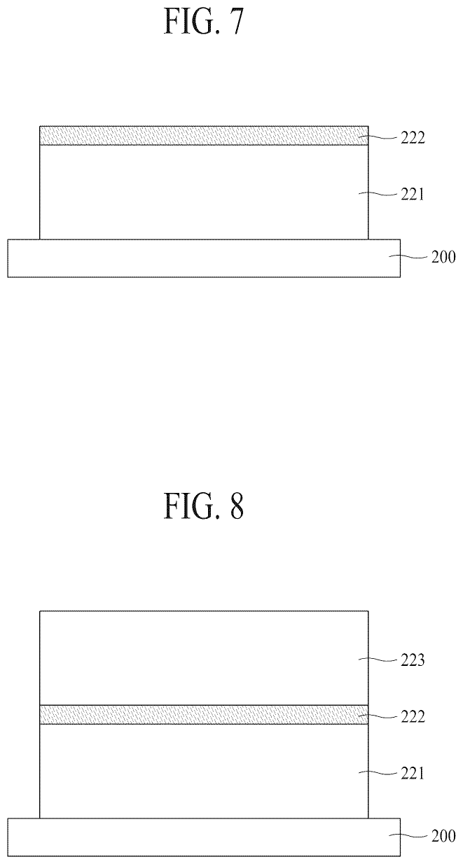

FIG. 7 is a schematic cross-sectional view of a gallium oxynitride layer according to another embodiment of the present disclosure.

As shown in FIG. 7, the gallium oxynitride layer according to another embodiment of the present disclosure includes a first gallium oxynitride layer 221 and a second gallium oxynitride layer 222. In this case, the first gallium oxynitride layer may be formed through a chemical vaporization deposition (CVD), and the second gallium oxynitride layer may be formed through an atomic layer deposition (ALD).

The first gallium oxynitride layer 221 is formed on the substrate 200. In this case, the substrate 200 may be a glass or silicon (Si) wafer, but is not limited thereto.

The first gallium oxynitride layer 221 may include an oxide semiconductor, for example, the first gallium oxynitride layer 221 may include a gallium oxynitride (GaON)-based oxide semiconductor containing gallium.

The first gallium oxynitride layer 221 may be formed using a chemical vaporization deposition (CVD). When the first gallium oxynitride layer 221 is formed using the chemical vaporization deposition method, the first gallium oxynitride layer 221 may be formed faster than a case using an atomic layer deposition method.

Meanwhile, the first gallium oxynitride layer 221 may be formed using plasma enhanced chemical vaporization deposition (PECVD).

The second gallium oxynitride layer 222 is formed on the first gallium oxynitride layer 221.

The second gallium oxynitride layer 222 may include an oxide semiconductor, for example, the second gallium oxynitride layer 222 may include a gallium oxynitride (GaON)-based oxide semiconductor containing gallium.

The second gallium oxynitride layer 222 may be formed using atomic layer deposition (ALD). Since the second gallium oxynitride layer 222 is formed using the atomic layer deposition method, the film quality of the second gallium oxynitride layer 222 is excellent.

Meanwhile, the second gallium oxynitride layer 222 may be formed using plasma enhanced atomic layer deposition (PEALD).

FIG. 8 is a schematic cross-sectional view of a gallium oxynitride layer according to another embodiment of the present disclosure.

As shown in FIG. 8, the gallium oxynitride layer according to another embodiment of the present disclosure includes a first gallium oxynitride layer 221, a second gallium oxynitride layer 222, and a third gallium oxynitride layer 223. Meanwhile, the gallium oxynitride layer according to an embodiment of FIG. 8 is the same as the gallium oxynitride layer according to an embodiment of FIG. 7, except for the third gallium oxynitride layer 223, and thus different configurations will be mainly described below.

The first gallium oxynitride layer 221 is formed using a chemical vaporization deposition method, and the second gallium oxynitride layer 222 is formed using an atomic layer deposition method.

The third gallium oxynitride layer 223 is formed on the second gallium oxynitride layer 222.

The third gallium oxynitride layer 223 may include an oxide semiconductor, for example, the third gallium oxynitride layer 223 may include a gallium oxynitride (GaON)-based oxide semiconductor containing gallium.

The third gallium oxynitride layer 223 may be formed using a chemical vaporization deposition (CVD). When the third gallium oxynitride layer 223 is formed using the chemical vaporization deposition method, the third gallium oxynitride layer 223 may be formed faster than a case using an atomic layer deposition method.

Meanwhile, the third gallium oxynitride layer 223 may be formed using plasma enhanced atomic layer deposition (PEALD).

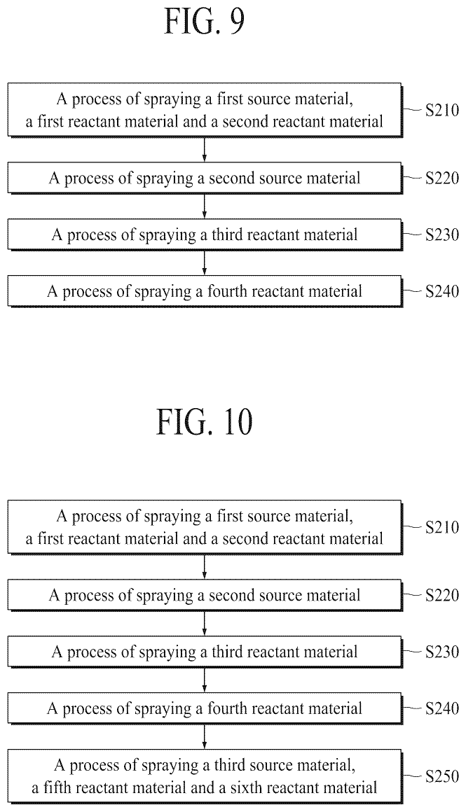

FIG. 9 is a schematic flowchart of a method of forming a gallium oxynitride layer according to another embodiment of the present disclosure.

As shown in FIG. 9, the method of forming a gallium oxynitride layer according to an embodiment of present disclosure includes a process S210 of injecting a first source material, a first reactant material, and a second reactant material, a process S220 of injecting a second source material, a process S230 of injecting a third reactant material, and a process S240 of injecting a fourth reactant material.

The process S210 of injecting the first source material, the first reactant material, and the second reactant material may use a chemical vaporization deposition (CVD). The process S210 of injecting the first source material, the first reactant material, and the second reactant material may be performed in a vacuum chamber, and specifically, the substrate 200 is placed on a susceptor provided below the vacuum chamber, and the first source material, the first reactant material, and the second reactant material are simultaneously injected onto the substrate 200 through a gas injection hole provided above the vacuum chamber, thereby forming a first gallium oxynitride layer (see 221 of FIGS. 7 and 8) on the substrate 200 by a chemical vaporization deposition method.

The first source material may be a material containing gallium (Ga). In this case, the first source material may include, for example, trimethyl gallium (TMGa).

The first reactant material may include any one of ammonia (NH3) and nitrogen (N2), and the second reactant material may include any one of oxygen (O2) and nitrous oxide (N2O).

When the first source material includes gallium (Ga), the first reactant material includes either ammonia (NH3) or nitrogen (N2), and the second reactant material includes either oxygen (O2) or nitrous oxide (N2O), gallium oxynitride (GaON) may be obtained as the first gallium oxynitride layer (see 221 of FIGS. 7 and 8).

When the process S210 of injecting the first source material, the first reactant material, and the second reactant material is performed, the first source material, the first reactant material, and the second reactant material may be injected without forming or forming plasma.

In this case, when plasma is not formed in the process S210 of injecting the first source material, the first reactant material, and the second reactant material, the first gallium oxynitride layer (see 221 of FIGS. 7 and 8) is formed using a chemical vaporization deposition method (CVD), and when plasma is formed in the process S210 of injecting the first source material, the first reactant material, and the second reactant material, the first gallium oxynitride layer (see 221 of FIGS. 7 and 8) may be formed using a plasma-enhanced chemical vaporization deposition method (PECVD). In this case, the plasma may include oxygen (O2).

The first gallium oxynitride layer (see 221 of FIGS. 7 and 8) may be formed by a chemical vaporization deposition method, and thus a deposition time may be shortened.

After the process S210 of injecting the first source material, the first reactant material, and the second reactant material, the process S220 of injecting the second source material, the process S230 of injecting the third reactant material, and the process S240 of injecting the fourth reactant material may be performed.

The process S220 of injecting the second source material, the process S230 of injecting the third reactant material, and the process S240 of injecting the fourth reactant material may use atomic layer deposition (ALD).

The second source material, the third reactant material, and the fourth reactant material may be injected onto the first gallium oxynitride layer (see 221 of FIGS. 7 and 8) through the gas injection hole to form the second gallium oxynitride layer (see 222 of FIGS. 7 and 8) on the first gallium oxynitride layer (see 221 of FIGS. 7 and 8) by an atomic layer deposition method.

When using the atomic layer deposition method, a process of injecting the second source material onto the first gallium oxynitride layer (see 221 of FIGS. 7 and 8), injecting the third reactant material, and then injecting the fourth reactant material may be repeated in one cycle.

In the process S220 of injecting the second source material, the second source material may include a material containing gallium (Ga). In this case, the material may be a precursor material or a gas material.

The material containing gallium (Ga) may be, for example, trimethyl gallium (TMGa). Meanwhile, the material containing gallium (Ga) is not limited thereto, and may be variously changed according to knowledge in the art.

After the process S220 of injecting the second source material, the process S230 of injecting the third reactant material may be performed.

When the second source material includes a material containing gallium (Ga), the third reactant material may include any one of ammonia (NH3) and nitrogen (N2).

When the process S230 of injecting the third reactant material is performed, the third reactant material may be injected without forming or forming plasma.

In this case, when plasma is not formed in the process S230 of injecting the third reactant material, the second gallium oxynitride layer is formed using atomic layer deposition (ALD), and when plasma is formed in the process S230 of injecting the third reactant material, the second gallium oxynitride layer may be formed using plasma reinforced atomic layer deposition (PEALD).

When the process S230 of injecting the third reactant material is performed using the plasma-enhanced atomic layer deposition method, the plasma may include oxygen (O2).

After performing the process S230 of injecting the third reactant material, the process S240 of injecting the fourth reactant material may be performed.

When the second source material includes gallium (Ga), the fourth reactant material may include any one of oxygen (O2) and nitrous oxide (N2O), and in this case, gallium oxynitride (GaON) may be obtained as the second gallium oxynitride layer (see 222 of FIGS. 7 and 8).

When the process S240 of injecting the fourth reactant material is performed, the fourth reactant material may be injected without forming or forming plasma.

In this case, when plasma is not formed in the process S240 of injecting the fourth reactant material, the second gallium oxynitride layer (see 222 of FIGS. 7 and 8) is formed using atomic layer deposition (ALD), and when plasma is formed in the process S240 of injecting the fourth reactant material, the second gallium oxynitride layer may be formed using plasma enhancement atomic layer deposition (PEALD).

When the process S240 of injecting the fourth reactant material is performed using the plasma-enhanced atomic layer deposition, the plasma may include oxygen (O2).

The second gallium oxynitride layer (see 222 of FIGS. 7 and 8) may be formed by atomic layer deposition (ALD or PEALD), and thus film quality may be excellent.

Although not shown, a process of injecting a purge gas may be added between the processes S210, S220, S230, and S240.

FIG. 10 is a schematic flowchart of a method of forming a gallium oxynitride layer according to another embodiment of the present disclosure.

As shown in FIG. 10, the method of forming a gallium oxynitride layer according to another embodiment of the present disclosure includes a process S210 of injecting a first source material, a first reactant material, and a second reactant material, a process S220 of injecting a second source material, a process S230 of injecting a third reactant material, a process S240 of injecting a fourth reactant material, and a process S250 of injecting a third source material, a fifth reactant material, and a sixth reactant material. In this case, the method of forming a gallium oxynitride layer according to FIG. 10 is the same as the method of forming a gallium oxynitride layer according to FIG. 9, except for the process S250 of injecting the third source material, the fifth reactant material, and the sixth reactant material, and thus different configurations will be mainly described below.

The process S250 of injecting the third source material, the fifth reactant material, and the sixth reactant material may use a chemical vaporization deposition (CVD).

Therefore, the process S250 of injecting the third source material, the fifth reactant material, and the sixth reactant material may be performed in a vacuum chamber.

Specifically, the substrate 200 in which the first gallium oxynitride layer and the second gallium oxynitride layer are formed is placed on a susceptor provided below the vacuum chamber, and the third source material, the fifth reactant material, and the sixth reactant material may be simultaneously injected through a gas injection hole provided above the vacuum chamber to form the third gallium oxynitride layer (see 223 in FIG. 8).

The process S250 of injecting the third source material, the fifth reactant material, and the sixth reactant material may be performed after the process S240 of injecting the fourth reactant material.

The third source material may be a material containing gallium (Ga). In this case, the third source material may include, for example, trimethyl gallium (TMGa).

The fifth reactant material may include any one of ammonia (NH3) and nitrogen (N2), and the sixth reactant material may include any one of oxygen (O2) and nitrous oxide (N2O).

When the third source material includes gallium (Ga), the fifth reactant material includes either ammonia (NH3) or nitrogen (N2), and the sixth reactant material includes either oxygen (O2) or nitrous oxide (N2O), gallium oxynitride (GaON) may be obtained as the third gallium oxynitride layer.

In the process S250 of injecting the third source material, the fifth reactant material, and the sixth reactant material, the third source material, the fifth reactant material, and the sixth reactant material may be injected without forming or forming plasma.

In this case, when plasma is not formed in the process S250 of injecting the third source material, the fifth reactant material, and the sixth reactant material, the third gallium oxynitride layer (see 223 in FIG. 8) is formed using a chemical vaporization deposition method (CVD), and when plasma is formed in the process S250 of injecting the third source material, the fifth reactant material, and the sixth reactant material, the third gallium oxynitride layer (see 223 in FIG. 8) may be formed using a plasma-enhanced chemical vaporization deposition method (PECVD). In this case, the plasma may include oxygen (O2).

The third gallium oxynitride layer 223 (see FIG. 8) may be formed by chemical vaporization deposition (CVD or PECVD), and thus a deposition time may be shortened.

Although not shown, a process of injecting a purge gas may be added between the processes S210, S220, S230, S240, and S250.

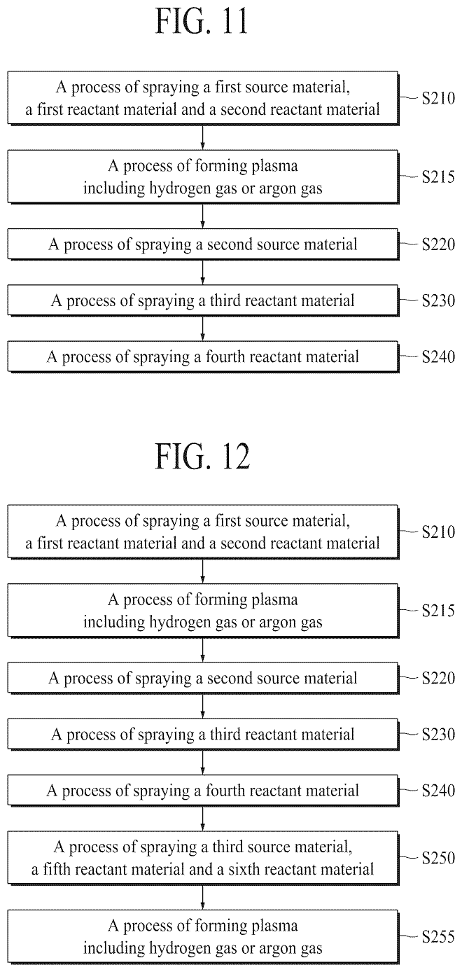

FIG. 11 is a schematic flowchart of a method of forming a gallium oxynitride layer according to another embodiment of the present disclosure.

As shown in FIG. 11, the method of forming a gallium oxynitride layer according to another embodiment of the present disclosure includes a process S210 of injecting a first source material, a first reactant material, and a second reactant material, a process S215 of forming plasma including hydrogen gas or argon gas, a process S220 of injecting a second source material, a process S230 of injecting a third reactant material, and a process S240 of injecting a fourth reactant material. In this case, the method of forming a gallium oxynitride layer according to FIG. 11 is the same as the method of forming a gallium oxynitride layer according to FIG. 9, except for the process S215 of forming the plasma including the hydrogen gas or argon gas, and thus different configurations will be mainly described below.

The process S215 of forming the plasma including hydrogen or argon gas may be performed after the process S210 of injecting the first source material, the first reactant material, and the second reactant material.

In the process S215 of forming the plasma containing the hydrogen or argon gas, the plasma containing the hydrogen gas (H2) or the argon (Ar) gas may be applied into the chamber. Specifically, in the process S210 of injecting the first source material, the first reactant material, and the second reactant material, the first reactant material, and the second reactant material may react to apply the plasma containing the hydrogen or argon gas to the substrate 200 on which the first gallium oxynitride layer is formed, and in this case, impurities remaining on the substrate 200 may be removed without reacting.

Therefore, the content of impurities in the surface or inside of the first gallium oxynitride layer formed through the process S210 of injecting the first source material, the first reactant material, and the second reactant material may be minimized.

Although not shown, a process of forming a plasma including hydrogen gas or argon gas may be further included between the process S220 of injecting the second source material and the process S230 of injecting the third reactant material. Also, after the process S240 of injecting the fourth reactant material, a process of forming a plasma including hydrogen gas or argon gas may be additionally included.

Although not shown, a process of injecting a purge gas may be added between each of the processes S210, S215, S220, S230, and S240.

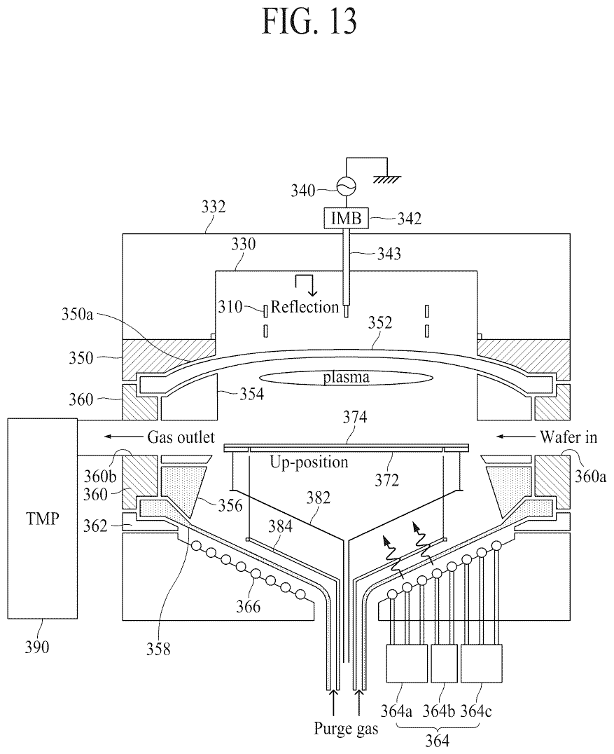

FIG. 12 is a schematic flowchart of a method of forming a gallium oxynitride layer according to another embodiment of the present disclosure.

As shown in FIG. 12, the method of forming a gallium oxynitride layer according to another embodiment of the present disclosure includes a process S210 of injecting a first source material, a first reactant material, and a second reactant material, a process S215 of forming plasma including hydrogen gas or argon gas, a process S220 of injecting a second source material, a process S230 of injecting a third reactant material, a process S240 of injecting a fourth reactant material, a process S255 of injecting a third source material, a fifth reactant material, and a sixth reactant material and a process S255 of forming a plasma including hydrogen gas or argon gas.

In this case, the method of forming the gallium oxynitride layer according to FIG. 12 is the same as the method of forming the gallium oxynitride layer according to FIG. 11 except for the process S250 of injecting the third source material, the fifth reactant material, and the sixth reactant material and the process S255 of forming plasma including the hydrogen gas or argon gas.

The process S250 of injecting the third source material, the fifth reactant material, and the sixth reactant material is the same as the process of injecting the third source material, the fifth reactant material, and the sixth reactant material according to FIG. 10. Accordingly, the process S250 of injecting the third source material, the fifth reactant material, and the sixth reactant material may use a chemical vaporization deposition method, and in this case, the third gallium oxynitride layer may be formed.

The process S255 of forming the plasma including hydrogen or argon gas may be performed after the process S250 of injecting the third source material, the fifth reactant material, and the sixth reactant material.

In the process S255 of forming the plasma including the hydrogen or argon gas, the plasma including the hydrogen gas (H2) or the argon (Ar) gas may be applied into the chamber. Specifically, the plasma including the hydrogen or argon gas may be applied on the third gallium oxynitride layer formed after the process S250 of injecting the third source material, the fifth reactant material, and the sixth reactant material.

When the plasma including hydrogen or argon gas is applied, impurities generated after the process S250 of injecting the third source material, the fifth reactant material, and the sixth reactant material may be removed. Therefore, the content of impurities on the surface or inside of the third gallium oxynitride layer formed may be minimized when the process S250 of injecting the third source material, the fifth reactant material, and the sixth reactant material is performed using chemical vaporization deposition.

Although not shown, a process of forming a plasma including hydrogen gas or argon gas may be further included between the process S220 of injecting the second source material and the process S230 of injecting the third reactant material. Also, a process of forming a plasma including hydrogen gas or argon gas may be further included between the process S240 of injecting the fourth reactant material and the process S250 of injecting the third source material, the fifth reactant material, and the sixth reactant material.

Although not shown, a process of injecting a purge gas may be added between each of the processes S210, S215, S220, S230, S240, S250 and S255.

FIG. 13 is a view illustrating a gallium oxynitride layer manufacturing apparatus according to another embodiment of the present disclosure.

Referring to FIG. 13, an apparatus for forming a gallium oxynitride layer according to an embodiment of the present disclosure includes an upper dome 352 and a lower dome 358 as an apparatus for depositing a gallium oxynitride layer. A step gas, that is, a source material and a reactant material may be injected into the upper dome 352, respectively, and the step gas, that is, a source material and a reactant material may be exhausted from the upper dome 352. The source material and the reactant material may be injected through a gas injection unit. The gas injection unit includes one or more injectors and may inject a step gas into the process Space by the one or more injectors. A process Space may be located under the upper dome 352. By supplying a purge gas to the lower dome 358 and supplying a step gas to the upper dome 352, deposition of an abnormal layer in the lower dome 358 may be suppressed by preventing the step gas from flowing to the lower dome 358. Also, by forming a uniform plasma, a uniform layer may be formed without rotating the substrate 374.

In addition, gallium oxynitride (GaON) of this step may be formed using a plasma enhanced ALD (PEALD) device using an inductively coupled plasma source.

The apparatus forming gallium oxynitride layer having the upper dome 352 and the lower dome 358 includes upper liners 354 and lower liners 356 to prevent unnecessary layer deposition on the inner wall of the chamber 360. The upper liners 354 and lower liners 356 may be periodically replaced or cleaned.

A lamp heater 366 disposed under the lower dome 358 is a ring-shaped lamp heater, and a plurality of lamp heaters 366 may be provided. The plurality of lamp heaters 366 may control power independently to uniformly heat the substrate 374.

The high vacuum pump 390 consisting of a turbo-molecular pump (TMP) connected to the exhaust part of the chamber 360 maintains a base vacuum inside the chamber 360, and accordingly, a stable plasma can be formed at a pressure of several torr or less even in the step.

The apparatus forming gallium oxynitride layer of the present disclosure may form a uniform layer on the substrate 374 at high speed by providing infrared rays reflected from the electromagnetic shielding housing 330 to the substrate 374 again while reducing performance degradation due to infrared heating of the antenna 310 forming the inductively coupled plasma disposed on the upper dome 352.

Referring to FIG. 13, an apparatus 300 forming a gallium oxynitride layer according to an embodiment of the present disclosure includes a chamber 360 with a sidewall; a substrate support part 372, which is provided inside the chamber and supports the substrate; an upper dome 352 covering the upper surface of the chamber 360 and formed of a transparent dielectric material; an antenna 310 placed above the upper dome 352 to form inductively coupled plasma; and an electromagnetic shielding housing 330 placed to surround the antenna 310. The electromagnetic shielding housing 330 may be heated by a heater.

The antenna 310 may include two one-turn unit antennas, and the two one-turn unit antennas may be connected in parallel to the RF power supply 340.

The antenna 310 may form the plasma in the process of forming hydrogen plasma performed after the process of injecting the reactant material and the process of forming the plasma performed between the process of injecting the source material and the process of injecting the reactant material.

The source material and the reactant material may be injected into the process spaces within the upper dome 352 and the lower dome 358 by an injector (not shown). The source material and the reactant material may be injected into the chamber 360 by the injector in the direction of the upper dome 352 or the horizontal direction.

The chamber 360 may be formed of a conductor, an inner space of the chamber 360 may have a cylindrical shape, and an outer shape of the chamber 360 may have a rectangular parallelepiped shape. The chamber 360 may be cooled by a coolant. The chamber 360, the upper dome 352, and the lower dome 358 are combined to provide a closed space.

A substrate inlet 360a may be provided on one side surface of the chamber 360 and an exhaust port 360b may be provided on the other side surface of the chamber 360 facing the substrate inlet 360a. The exhaust port 360b may be connected to the high vacuum pump 390. The high vacuum pump 390 may be a turbo-molecular pump. The high vacuum pump 390 may maintain a low base pressure and may maintain a pressure of several torr or less even during the step. The upper surface of the exhaust port 360b may be the same as or lower than the upper surface of the substrate inlet 360a.

The upper dome 352 may be made of a transparent dielectric material such as quartz, sapphire, or ceramic. The upper dome 352 may be made of a ceramic material. The ceramic material has better corrosion resistance than quartz.

The upper dome 352 may be inserted into a jaw formed on the upper surface of the chamber 360 and coupled to the chamber 360. For vacuum sealing, a coupling portion of the upper dome 352 coupled to the chamber 360 may have a washer shape. The upper dome 352 may have an arc shape or an ellipse shape. The upper dome 352 may transmit infrared rays incident from the lower portion.

Infrared rays reflected from the electromagnetic shielding housing 330 may pass through the upper dome 352 and enter the substrate 374.

The lower dome 358 may be made of quartz or sapphire as a transparent dielectric. The lower dome 358 may include a washer-shaped coupling portion coupled to a jaw formed on the lower surface of the chamber 360, a lower dome body having a funnel shape extending below the coupling portion, and a cylindrical pipe extending downward from the center of the lower dome body. The lower dome 358 may be inserted into a jaw formed on the lower surface of the chamber 360 and coupled to the chamber 360. For vacuum sealing, a coupling portion of the lower dome 358 coupled to the chamber 360 may have a washer shape.

The driving shaft of the first lifter 384 and the driving shaft of the second lifter 382 may be disposed to be inserted into the cylindrical pipe of the lower dome 358. The purge gas supplied through the lower dome 358 may be supplied through a flow path. The flow path may be a cylindrical pipe of the lower dome 358. The purge gas may be an inert gas such as argon.

The upper liner 354 may be made of a transparent dielectric material. For example, the upper liner 354 may be made of quartz, alumina, sapphire, or aluminum nitride. The upper liner 354 may be made of a material that suppresses deposition of an abnormal layer.

The insulation part 362 may be disposed between the lower surface of the chamber 360 and the reflector 361 and may have a ring shape. The insulation part 362 may reduce heat transfer from the heated reflector 361 to the chamber 360. The insulation part 362 may be made of ceramic. The upper surface of the insulation part 362 may include a jaw. A jaw of the insulation part 362 and a jaw of the lower surface of the chamber 360 may accommodate and vacuum-seal the washer-shaped coupling portion of the lower dome 358.

The concentric-shaped lamp heater 366 may include a plurality of concentric-shaped ring-shaped lamp heaters and may be connected to a power source 364. The concentric-shaped ring-shaped lamp heater 366 may be disposed along the inclined surface of the lower dome 358 at regular intervals, and the concentric-shaped lamp heater 366 may be divided into three groups to receive power independently from each other. The concentric-shaped ring-shaped lamp heater 366 may be inserted into a ring-shaped groove formed on the inclined surface of the reflector 361 to be aligned.

For example, the concentric-shaped lamp heater 366 may be a halogen lamp heater, and there may be eight lamp heaters. The lower three lamp heaters may form a first group, the middle two lamp heaters may form a second group, and the upper three lamp heaters may form a third group. The first group may be connected to a first power source 364a, the second group may be connected to a second power source 364b, and the third group may be connected to a third power source 364c. The first to third power sources 364a to 364c may be independently controlled for uniform heating of the substrate.

The RF power supply 340 may supply RF power to the antenna 310 through an impedance matching box 342 and a power supply line 343. The antenna 310 through which an RF current flows must secure a sufficient cross-sectional area for a high current, and preferably forms a closed loop to form a sufficient magnetic flux. The antenna 310 may use a vertically erected strip line to absorb infrared rays incident from the upper or lower portion thereof and to minimize an increase in resistance due to heating. The antenna 310 provides high light transmittance to infrared rays.

Also, the antenna 310 may be coated with gold (Au) or silver (Ag) to increase infrared reflection. Also, in order to secure sufficient magnetic flux, the antenna 310 having a two-layer structure may be used. In the one-turn unit antenna, a position where RF power is supplied is disposed on an upper surface, so that power loss due to capacitive coupling may be reduced.

The lower dome 358 may cover the lower surface of the chamber 360 and may be formed of a transparent dielectric material, and may have the same curvature as the upper dome 352. The lamp heater 366 may be disposed on the lower surface of the lower dome 358. The reflector 361 may be disposed on the lower surface of the lamp heater 366.

In addition, a control unit (not shown) for controlling the RF power source 340 may be further included. Here, for example, the source material supply path (not shown) for supplying the source gas and the reactant material supply path (not shown) may be formed separately.

Meanwhile, a substrate may be mounted on the substrate support part 372 into the chamber 360 for the process of forming a layer. The substrate 374 may include various substrates for forming a gallium oxynitride (GaON) layer.

The substrate support part 372 may be provided with, for example, an electrostatic chuck or the like so that the substrate 374 may be seated and supported to adsorb and maintain the substrate 374 by electrostatic force, or to support the substrate 374 by vacuum adsorption or mechanical force.

The clamp 350 may be disposed to cover the edge of the upper dome 352. The clamp 350 is formed of a conductor, and may be cooled by cooling water. The lower surface of the clamp 350 has a jaw to be coupled to the washer-shaped coupling portion of the upper dome 352, and may include a curved portion 350a to cover a portion of the curved portion of the upper dome 352. The curved portion 350a of the clamp 350 may be gold-plated to reflect infrared rays. The inner diameter of the clamp 350 may be substantially the same as the inner diameter of the upper liner 354. Also, the inner diameter of the clamp 350 may be the same as the diameter of the electromagnetic shielding housing 330.

The chamber housing 332 may be disposed on the clamp 350 and may be disposed to cover the electromagnetic shielding housing 330.

Meanwhile, a gas containing gallium (Ga) may be supplied as the source material, and a gas containing oxygen (O) may be supplied as the reactant material. Here, the source material, for example, the gas containing gallium (Ga) may include trimethyl gallium (TMGa) gas, and the reactant material, for example, the gas containing oxygen may include oxygen (O2) gas or nitrous oxide (N2O) gas.

Accordingly, the present disclosure may have the following advantages.

According to the present disclosure, the first gallium oxide layer is formed by atomic layer deposition (ALD), and the second gallium oxide layer is formed by chemical vaporization deposition (CVD), so that the film quality of the gallium oxide layer including the first gallium oxide layer and the second gallium oxide layer is excellent and the speed at which the gallium oxide layer is formed can be increased.

According to the present disclosure, the first gallium oxide layer is formed by atomic layer deposition (ALD), the second gallium oxide layer is formed by chemical vaporization deposition (CVD), and the third gallium oxide layer is formed by atomic layer deposition (ALD), thereby improving the film quality of the gallium oxide layer including the first gallium oxide layer to the third gallium oxide layer and increasing the speed at which the gallium oxide layer is formed.

According to present disclosure, when depositing the first gallium oxynitride layer using atomic layer deposition (ALD), plasma is applied between the process of injecting the first source material and the process of injecting the first reactant material, and plasma is applied after the process of injecting the second reactant material, thereby preventing the generation of impurities by the first source material, the first reactant material, and the second reactant material.

According to present disclosure, when depositing the third gallium oxynitride layer using atomic layer deposition (ALD), plasma is applied between the process of injecting the third source material and the process of injecting the fifth reactant material, and plasma is applied after the process of injecting the sixth reactant material, thereby preventing the generation of impurities by the third source material, the fifth reactant material, and the sixth reactant material.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

1. A method of forming the gallium oxynitride layer comprising:
a process of injecting a source material containing gallium;
a process of forming a gallium nitride layer by injecting a first reactant material containing nitrogen; and
a process of forming a gallium oxynitride layer by injecting a second reactant material containing oxygen onto the gallium nitride layer.

2. The method of forming the gallium oxynitride layer according to claim 1,
wherein the source material includes trimethyl gallium (TMGa).

3. The method of forming the gallium oxynitride layer according to claim 1,
wherein the first reactant material includes any one of nitrogen (N₂) and ammonia (NH₃).

4. The method of forming the gallium oxynitride layer according to claim 1,
wherein the second reactant material includes any one of oxygen (O₂) and nitrous oxide (N₂O).

5. The method of forming the gallium oxynitride layer according to claim 1, further comprising:
a process of forming a plasma containing hydrogen (H₂) gas or argon (Ar) gas between the process of injecting the source material and the process of injecting the first reactant material.

6. The method of forming the gallium oxynitride layer according to claim 1,
wherein the process of injecting the first reactant material includes a process of forming plasma containing oxygen.

7. The method of forming the gallium oxynitride layer according to claim 1, further comprising:
a process of forming a plasma containing hydrogen (H₂) gas or argon (Ar) gas after the process of injecting the second reactant material.

8. A method of forming a gallium oxynitride layer comprising:
a process of forming a first gallium oxynitride layer on a substrate; and
a process of forming a second gallium oxynitride layer on the first gallium oxynitride layer,
wherein any one of the process of forming the first gallium oxynitride layer and the process of forming the second gallium oxynitride layer uses an atomic layer deposition method (ALD), and another one of the process of forming the first gallium oxynitride layer and the process of forming the second gallium oxynitride layer uses a chemical vaporization deposition method (CVD).

9. The method of forming the gallium oxynitride layer according to claim 8,
wherein the process of forming the first gallium oxynitride layer uses an atomic layer deposition method (ALD), and the process of forming the second gallium oxynitride layer uses a chemical vaporization deposition method (CVD).

10. The method of forming the gallium oxynitride layer according to claim 9, further comprising:
a process of forming a third gallium oxynitride layer on the second gallium oxynitride layer,
wherein the process of forming the third gallium oxynitride layer uses an atomic layer deposition method (ALD).

11. The method of forming the gallium oxynitride layer according to claim 8,
wherein the process of forming the first gallium oxynitride layer uses a chemical vaporization deposition method (CVD), and the process of forming the second gallium oxynitride layer uses an atomic layer deposition method (ALD).

12. The method of forming the gallium oxynitride layer according to claim 11, further comprising:
a process of forming a third gallium oxynitride layer on the second gallium oxynitride layer,
wherein the process of forming the third gallium oxynitride layer uses a chemical vaporization deposition method (CVD).

13. The method of forming the gallium oxynitride layer according to claim 8,
wherein a process of forming any one of the first gallium oxynitride layer and the second gallium oxynitride layer using the atomic layer deposition method (ALD) comprises:
a process of injecting a source material containing gallium;
a process of forming a gallium nitride layer by injecting a first reactant material containing nitrogen; and
a process of forming a gallium oxynitride layer by injecting a second reactant material containing oxygen onto the gallium nitride layer.

14. The method of forming the gallium oxynitride layer according to claim 8,
wherein a process of forming any one of the first gallium oxynitride layer and the second gallium oxynitride layer using the chemical vaporization deposition method (CVD) includes a process of injecting a source material including gallium (Ga), a first reactant material including nitrogen, and a second reactant material including oxygen.

15. The method of forming the gallium oxynitride layer according to claim 14,
wherein the source material includes trimethyl gallium (TMGa),
the first reactant material includes any one of nitrogen (N₂) and ammonia (NH₃),
and the second reactant material includes any one of oxygen (O₂) and nitrous oxide (N2O).

16. The method of forming the gallium oxynitride layer according to claim 14, further comprising:
a process of forming plasma containing hydrogen (H₂) gas or argon (Ar) gas after the process of injecting the source material, the first reactant material and the second reactant material.

17. The method of forming the gallium oxynitride layer according to claim 14,
wherein the process of injecting the source material, the first reactant material, and the second reactant material includes a process of forming plasma including an oxygen.

18. A method of forming a gallium oxynitride layer in a chamber including an upper dome, a lower dome and a heater comprising:
a process of injecting a source material containing gallium (Ga) onto a substrate disposed in the chamber;
a process of forming a gallium nitride layer by injecting a first reactant material containing nitrogen; and
a process of forming the gallium oxynitride layer by injecting a second reactant material containing oxygen onto the gallium nitride layer.
